(19) United States
(12) Patent Application Publication
(10) Pub. No.: US 2009/0319873 A1
(43) Pub. Date: Dec. 24, 2009

(54) SIGNAL PROCESSING DEVICE AND SIGNAL PROCESSING METHOD THAT DECODE ENCODED INFORMATION

(75) Inventors: Kazuaki DOI, Yokohama-shi (JP); Yutaka KASHIHARA, Chigasaki-shi (JP)

Correspondence Address: KNOBBE MARTENS OLSON & BEAR LLP, 2040 MAIN STREET, FOURTEENTH FLOOR, IRVINE, CA, 92614, US

(73) Assignee: KABUSHIKI KAISHA TOSHIBA, Tokyo (JP)

(21) Appl. No.: 12/469,591

(22) Filed: May 20, 2009

(30) Foreign Application Priority Data
Jun. 23, 2008 (JP) 2008-163773

(51) Int. Cl. H03M 13/05; G06F 11/08; G06F 11/10

(52) U.S. Cl. 714/777; 714/780; 714/E11.032; 714/E11.031

(57) ABSTRACT

According to an embodiment of the present invention provides the signal processing system. In the signal processing device that estimates information data from a reception signal by performing iterative processing between a demodulator that demodulates data of n(>m) bits obtained by modulating data of m bits into m bits and an ECC decoder and carrying out maximum a posteriori probability decoding, the device has a module that calculates an a posteriori value after demodulation by performing calculation of modulation data having a pattern estimated to have a high probability alone as modulation data to be decoded from all patterns of the modulation data to be decoded when effecting calculation of the a posteriori value after demodulation based on an a priori value fed back from the ECC decoder at the time of effecting modulation for a second or subsequent time.

### CROSS-REFERENCE TO RELATED APPLICATIONS

This application is based upon and claims the benefit of priority from Japanese Patent Application No. 2008-163773, filed Jun. 23, 2008, the entire contents of which are incorporated herein by reference.

### BACKGROUND

1. Field

One embodiment of the present invention relates to a signal processing device and a signal processing method that decodes encoded information. Further, there is provided an invention that is effective for use in, e.g., a decoding device that decodes encoded information, a decoding method, a decoding program, a recording medium thereof, and a reproducing apparatus including the decoding device.

2. Description of the Related Art

In recent years, an amount of digital information stored in a storage device is exponentially increased as various kinds of information including image information, audio information, programs, and others are digitized. With this increase, development of a storage device suitable for realization of high capacity and high density has been advanced.

It is expected that the signal-to-noise ratio of a reproduction signal is degraded when realization of high capacity and high density of a storage device advances. Therefore, to obtain the same signal reading grade as that in the conventional technology, signal processing technologies that can improve a quality of a reproduction signal even in a region having a low signal-to-noise ratio or correct an error are required.

As one of such signal processing technologies, an iterative decoding scheme utilizing an error correcting code, e.g., a turbo code or a low-density parity check (LDPC) code is attracting attention in recent years, and application of the iterative decoding scheme to a storage field are actively studied. According to the iterative decoding scheme, since an obtained reproduction signal can be repeatedly decoded, an error correcting capability close to a theoretical characteristic limit (a Shannon limit) can be obtained.

Furthermore, not only the error correcting code technology, e.g., the iterative decoding scheme but also a structure of a modulation code or a demodulation method suitable for recording/reproduction in a high-capacity storage are studied and developed. Patent Document 1 (JP-A 1997-197947) and other schemes are proposed in relation to a structure of a modulation code, and Patent Document 2 (JP-A 2007-272973) and other schemes are proposed in regard to a demodulation method. The iterative decoding scheme utilizing an error correcting code, e.g., a turbo code or an LDPC code is disclosed in Patent Document 3 (JP-A 2003-168264).

However, the conventional technology has the following problem. In a demodulator disclosed in Patent Document 2, since an a posteriori value of error correction code (ECC) data is calculated based on probabilities of all patterns of a demodulation code, a demodulation calculation amount is dependent on the number of patterns of demodulation data. Therefore, since the number of patterns of the demodulation code raised to the mth power) exponentially rises when the number of bits m of information data is increased, a noticeable increase in demodulation calculation amount is a problem.

### BRIEF DESCRIPTION OF THE SEVERAL VIEWS OF THE DRAWINGS

A general architecture that implements the various feature of the invention will now be described with reference to the drawings. The drawings and the associated descriptions are provided to illustrate embodiments of the invention and not to limit the scope of the invention.

FIG. 1 is a block diagram showing a structural example of a conventional recording/reproducing apparatus;

FIG. 2 is a view showing a structure of a 2:4 modulation code;

FIG. 3 is a view showing a structural example of a demodulator depicted in FIG. 1;

FIG. 4 is a view showing a structural example of a reception signal input to the demodulator depicted in FIG. 1;

FIG. 5 is a view showing an example of a signal processing system that iteratively performs decoding between a demodulator and a turbo/LDPC decoder as a premise of the present invention;

FIG. 6 is a view showing a structural example of a demodulator 30 depicted in FIG. 5;

FIG. 7 is a signal processing system block diagram in an embodiment according to the present invention;

FIG. 8 is a view showing a structural example of a demodulator 40 depicted in FIG. 7;

FIG. 9 is a flowchart showing an operation of the demodulator 40 depicted in FIG. 8;

FIG. 10 is a view showing a structural example of a reliability calculation module 401 depicted in FIG. 8;

FIG. 11 is a view showing a structural example of a data address extraction module 401 and a data determination module 4011 depicted in FIG. 10;

FIG. 12 is a view showing a structural example of a reliability calculation module 4013 depicted in FIG. 10;

FIG. 13 is a view showing a structural example of a data selection module 402 depicted in FIG. 8;

FIG. 14 is a view showing a structural example of an a posteriori calculation module 403 depicted in FIG. 8;

FIG. 15 is a view showing a structural example of an a posteriori value calculator 4031 depicted in FIG. 14;

FIG. 16 is a view showing an example of a reception signal for modulation data;

FIG. 17 is an explanatory view of a relationship between a probability distribution of a reception signal for ECC data and a threshold value utilized to determine reliability of an a priori value of the ECC data;

FIG. 18 is a view showing a distribution example of an a posteriori value of the ECC data;

FIG. 19 is a view showing a distribution example of an a posteriori value of ECC data (=0);

FIG. 20 is a view showing a setting example of an a posteriori value of ECC data that maximizes a proportion of the data;

FIG. 21 is a view for explaining an example of conversion from an a posteriori value of the ECC data (=0) to a receive signal for the ECC data;

FIG. 22 is a view showing a probability distribution of the reception signal for the ECC data (=0);

FIG. 23 is a table showing a setting example of threshold values in the reliability calculation module and data selection module;

FIG. 24 is a table showing a correspondence example of a Hamming distance and reliability of modulation data in the reliability calculation module; and

FIG. 25 is a table showing a determination reference example of an a posteriori value calculation addresses in the a posteriori value calculation module.

### DETAILED DESCRIPTION

Various embodiments according to the invention will be described hereinafter with reference to the accompanying drawings.

An embodiment according to the present invention provides a decoding device that has a calculation amount smaller than that in the conventional technology and enables decoding with a high error correcting capability in a signal processing system that iteratively perform decoding in a demodulator and a turbo/LDPC decoder.

A decoding device in an embodiment according to the present invention is characterized by selecting modulation data having a high possibility of transmission from 2̂m (=2 raised to the mth power) types of modulation data based on an a posteriori value of ECC data input to a demodulator when performing demodulation for a second or subsequent time and obtaining an a posteriori value of the ECC data based on the selected modulation data.

That is, the present invention is a signal processing device that performs iterative processing between the demodulator that demodulates data of n (>m) bits obtained by modulating data of m bits based on a predetermined modulation rule into data of m bits and an ECC decoder, carries out maximum a posteriori probability decoding, and estimates information data from a reception signal for modulation data based on this processing.

Moreover, this signal processing device is characterized by having a module that performs calculation of modulation data having a pattern that is assumed to have a high probability as modulation data to be decoded alone from all patterns of the modulation data to be decoded and thereby calculates an a posteriori value after demodulation when calculating the a posteriori value after demodulation based on an a priori value fed back from the ECC decoder.

In the signal processing device, an amount of calculation is small, and decoding with a high error correcting capability can be performed.

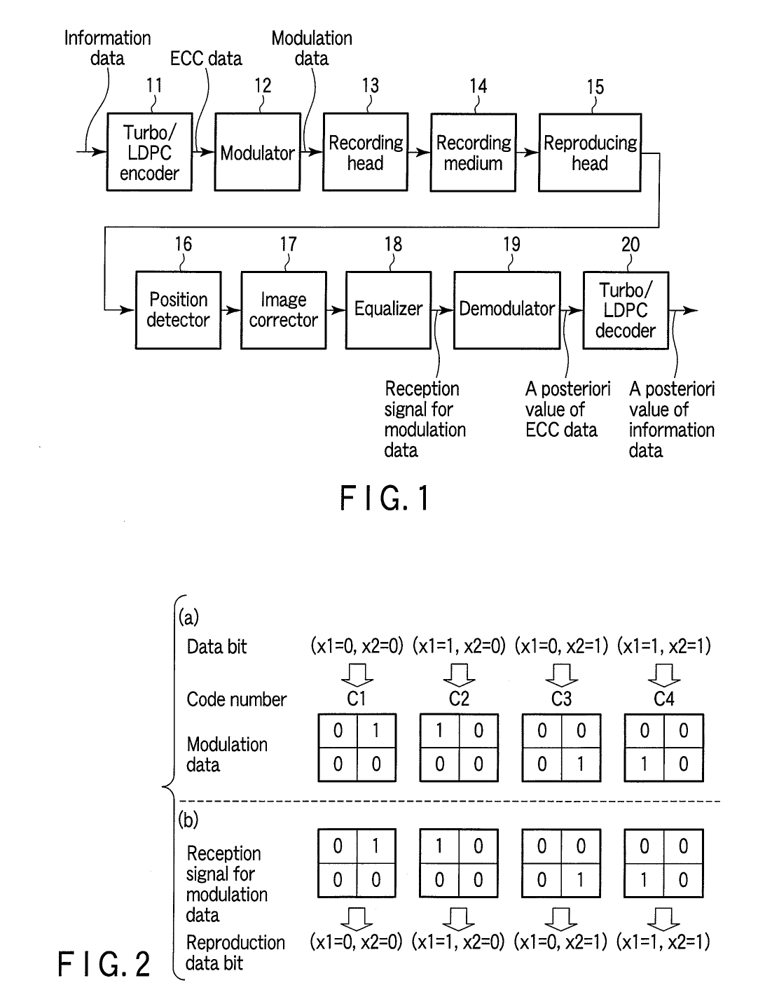

The decoding device that is a premise of the present invention will be first explained. FIG. 1 is a block diagram showing a structure of a recording/reproducing apparatus based on an embodiment in Patent Document 2.

When recording data, information data to be recorded is encoded into ECC data by, e.g., a turbo encoder or an LDPC encoder 11. Then, the ECC data is input to a modulator 12 to be converted into modulation data. At last, a recording head 13 is utilized to record the modulation data in a recording medium 14, thereby terminating the processing. As the recording medium, there is, e.g., a hologram storage medium.

When reproducing recorded data, information consisting of two-dimensional page data recorded in the hologram storage medium is read through a reproducing head 15 to generate a reproduction signal corresponding to the two-dimensional page data. A position detector 16 detects a position of an image with respect to the generated reproduction signal, and then an image corrector 17 or an equalizer 18 corrects the reproduction signal.

In demodulation processing and an error correction processing part, a reception signal for the modulation data output from the equalizer 18 is first input to a demodulator 19 to calculate an a posteriori value of the ECC data. Then, the a posteriori value of the ECC data calculated in the demodulator 19 is input to a turbo/LDPC decoder 20, and iterative decoding is executed in the decoder 20 to obtain an a posteriori value of information data. Additionally, the a posteriori value of the information data is subjected to hard determination, and the processing is terminated upon determining the information data.

A modulation method for the information data and a calculation method for the a posteriori value of the ECC data in the demodulator will now be explained.

Although various methods have been conventionally proposed as the modulation method, 2:4 modulation will be explained as an example. FIG. 2 shows a structure of a 2:4 modulation code.

As indicated by a position of a code (a) in FIG. 2, in 2:4 modulation, data of two bits (corresponding to the ECC data in FIG. 1) is converted into modulation data of four bits including two rows and two columns. For example, when both pieces of two-bit data x1 and x2 are zero, a code C1 is selected as modulation data, and it is converted into two-dimensional data in which an upper right bit is one and other bits are zero. It is to be noted that a reception signal corresponding to four bits is converted into two data bits as indicated by a position of a code (b) in FIG. 2 at the time of reproduction.

As explained above, in 2:4 demodulation, data bits are not processed one by one but they are processed in units of two bits at the time of recording and reproduction.

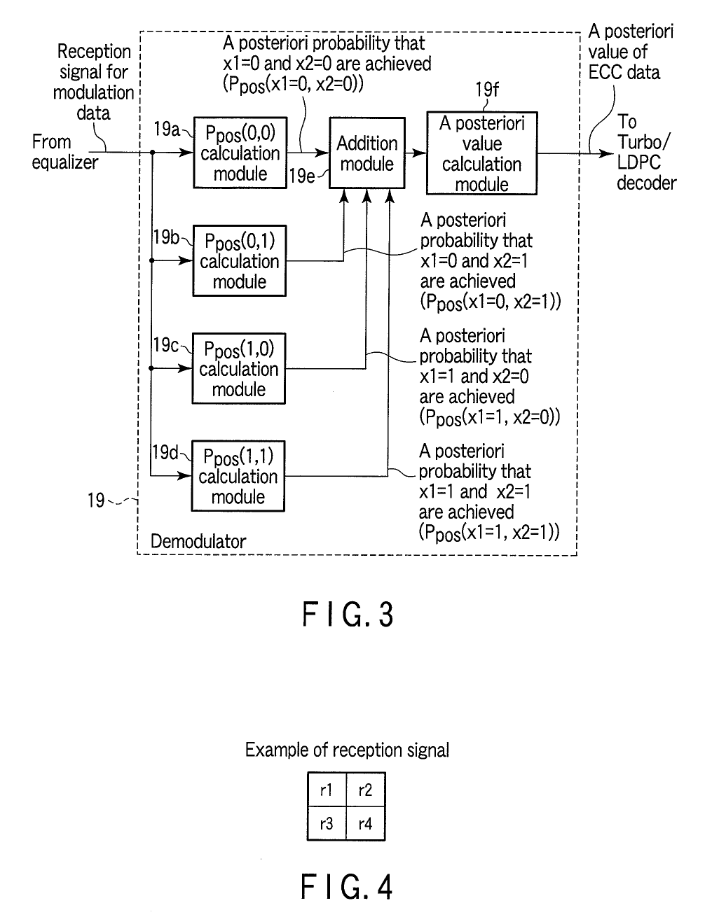

In the demodulator 19, when calculating each a posteriori value of the ECC data, each a posteriori value of the ECC data consisting of two bits is calculated from a reception signal of four bits. FIG. 3 is a structural view of a demodulator based on Patent Document 2.

A reception signal of four bits is first input to a P_{POS}(x1=0, x2=0) calculation module 19a to a P_{POS}(x1=1, x2=1) calculation module 19d. When this reception signal is input, the respective calculation modules 19a to 19d output an a posteriori probability P_{POS}(x1=0, x2=0) that x1=0 and x2=0 are achieved to an a posteriori probability P_{POS}(x1=1, x2=1) that x1=1 and x2=1 are achieved.

Then, the respective a posteriori probabilities are input to an addition module 19e to output an a posteriori probability P_{POS}(x1=0) that x1=0 is achieved, an a posteriori probability P_{POS}(x1=1) that x1=1 is achieved, an a posteriori probability P_{POS}(x2=0) that x2=0 is achieved, and an a posteriori probability P_{POS}(x2=1) that x2=1 is achieved. At last, an a posteriori value calculation module 19f obtains an a posteriori value V_{POS}(x1) of x1 and an a posteriori value V_{POS}(x2) of x2 from the respective a posteriori probabilities, thereby terminating the calculation of the a posteriori values.

Several patterns of a calculation method for a posteriori probabilities output from the P_{POS}(x1=0, x2=0) calculation module 19a to P_{POS}(x1=1, x2=1) calculation module 19d are introduced in Patent Document 2. A method utilizing Euclidean distances of a reception signal and modulation data will be explained here. FIG. 4 shows a structural example of a reception signal input to the demodulator 19.

Euclidean distances yd(C1) to yd(C4) of the reception signal and respective pieces of modulation data are as represented by Expressions 1 to 4.

yd(C1)=\sqrt{r1²+(r2−1)²+r3²+r4²} Expression 1

yd(C2)=\sqrt{(r1−1)²+r2²+r3²+r4²} Expression 2

yd(C3)=\sqrt{r1²+r2²+r3²+(r4−1)²} Expression 3

yd(C4)=\sqrt{r1²+r2²+(r3−1)²+r4²} Expression 4

The Euclidean distances affect respective a posteriori probabilities. When noise included in the reception signal for the modulation data is additive white gaussian noise having an average value of zero and a standard deviation of σ, probabilities P_{POS}(x1=0, x2=0) to P_{POS}(x1=1, x2=1) are as represented by Expressions 5 to 8.

$$\begin{matrix}{P}_{pos} ( x 1 = 0 , x 2 = 0 ) = {( \frac{1}{\sqrt{2 π} σ} )}^{4} {e}^{- \frac{y {d ( c 1 )}^{2}}{2 {σ}^{2}}} & Expression 5 \\ {P}_{pos} ( x 1 = 1 , x 2 = 0 ) = {( \frac{1}{\sqrt{2 π} σ} )}^{4} {e}^{- \frac{y {d ( c 2 )}^{2}}{2 {σ}^{2}}} & Expression 6 \\ {P}_{pos} ( x 1 = 0 , x 2 = 1 ) = {( \frac{1}{\sqrt{2 π} σ} )}^{4} {e}^{- \frac{y {d ( c 3 )}^{2}}{2 {σ}^{2}}} & Expression 7 \\ {P}_{pos} ( x 1 = 1 , x 2 = 1 ) = {( \frac{1}{\sqrt{2 π} σ} )}^{4} {e}^{- \frac{y {d ( c 4 )}^{2}}{2 {σ}^{2}}} & Expression 8\end{matrix}$$

Since the standard deviation σ of noise varies depending on a noise amount produced by, e.g., a reproducing head, it must be specifically obtained. Noise included in the reception signal for the modulation data that can be a basis for calculation of a value of σ can be obtained as follows. That is, known modulation data is prepared in advance, recording and reproduction are performed to obtain a reception signal for the modulation data, and a difference between the known modulation data and the reception signal is calculated, whereby the noise can be obtained. Therefore, there is a method of determining a standard deviation of this difference signal as σ.

If a fact that σ does not vary in accordance with each medium is confirmed in advance, an appropriate value may be stored in the apparatus in advance, and this value may be used for calculation.

When P_{POS}(x1=0, x2=0) to P_{POS}(x1=1, x2=1) are utilized, P_{POS}(x1=0) to P_{POS}(x2=1) calculated by the addition module 19e are as represented by Expressions 9 to 12.

Pₚₒₛ(x1=0)=Pₚₒₛ(x1=0,x2=0)+Pₚₒₛ(x1=0,x2=1) Expression 9

Pₚₒₛ(x1=1)=Pₚₒₛ(x1,x2=0)+Pₚₒₛ(x1=1,x2=1) Expression 10

Pₚₒₛ(x2=0)=Pₚₒₛ(x1=0,x2=0)+Pₚₒₛ(x1=1,x2=0) Expression 11

Pₚₒₛ(x=1)=Pₚₒₛ(x1=0,x2=1)+Pₚₒₛ(x1=1,x2=1) Expression 12

When P_{POS}(x1=0) to P_{POS(x2=}1) are utilized, V_{POS}(x1) and V_{POS}(x2) calculated by the a posteriori value calculation module 19f are as represented by Expressions 13 and 14.

$$\begin{matrix}{V}_{pos} ( x 1 ) = log \frac{{P}_{pos} ( x 1 = 1 )}{{P}_{pos} ( x 1 = 0 )} & Expression 13 \\ {V}_{pos} ( x 2 ) ≃ log \frac{{P}_{pos} ( x 2 = 1 )}{{P}_{pos} ( x 2 = 0 )} & Expression 14\end{matrix}$$

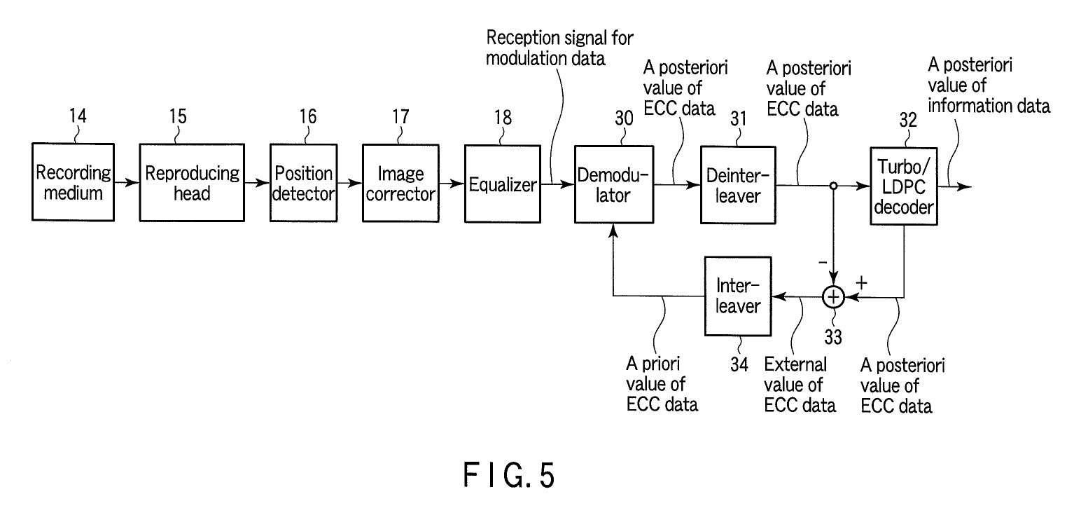

Consideration will now be given to a signal processing system in which technologies disclosed in Patent Document 2 and Patent Document 3 are combined and iterative decoding is carried out between a demodulator 30 and a turbo/LDPC decoder 32. In this case, it can be considered that the signal processing system has a structure depicted in FIG. 5.

A recording medium 14, a reproducing head 15, a position detector 16, an image corrector 17, and an equalizer 18 are the same as those in the structure depicted in FIG. 1.

A reproduction signal for demodulation data output from an adaptive equalizer 18 and an a priori value of ECC data are first input to a demodulator 30 to obtain an a posteriori value of the ECC data. After respective pieces of data are reordered by a deinterleaver 31, the a posteriori value of the ECC data output from the demodulator 30 is input to a turbo/LDPC decoder 32.

In the turbo/LDPC decoder 32, iterative decoding is carried out in the decoder based on the input a posteriori value of the ECC data.

When the number of iterations between the demodulator 30 and the turbo/LDPC decoder 32 has reached a predetermined number of times, or when an error is not detected as a consequence of performing a CRC or an error check based on a check matrix with respect to a decoding result, the turbo/LDPC decoder 32 calculates an a posteriori value of information data and terminates the decoding processing.

Contrary, when the number of iterations between the demodulator 30 and the turbo/LDPC decoder 32 does not reach the predetermined number of times and an error is detected as a consequence of performing a CRC or an error check based on a check matrix, the turbo/LDPC decoder 32 updates and outputs the a posteriori value of the ECC data.

When the a posteriori value of the ECC data is calculated, a subtracter 33 subtracts the a posteriori value of the ECC data before updating that is input to the turbo/LDPC decoder 32 from the a posteriori value of the ECC data after updating that is output from the turbo/LDPC decoder 32 in order to obtain an a priori value of the ECC data that is used in the demodulator 30. A subtraction result is an external value of the ECC data.

The external value of the ECC data is input to the demodulator 30 as an a priori value of the ECC data after respective pieces of data are reordered by an interleaver 34. The a priori value of the ECC data input to the demodulator 30 and the reproduction signal for the modulation data are utilized for recalculation of the a posteriori value of the ECC data in the demodulator 30.

The above-explained operation continues until the number of iterations between the demodulator 30 and the turbo/LDPC decoder 32 reaches the predetermined number of times or until an error is no longer detected by the CRC or the error check based on a check matrix.

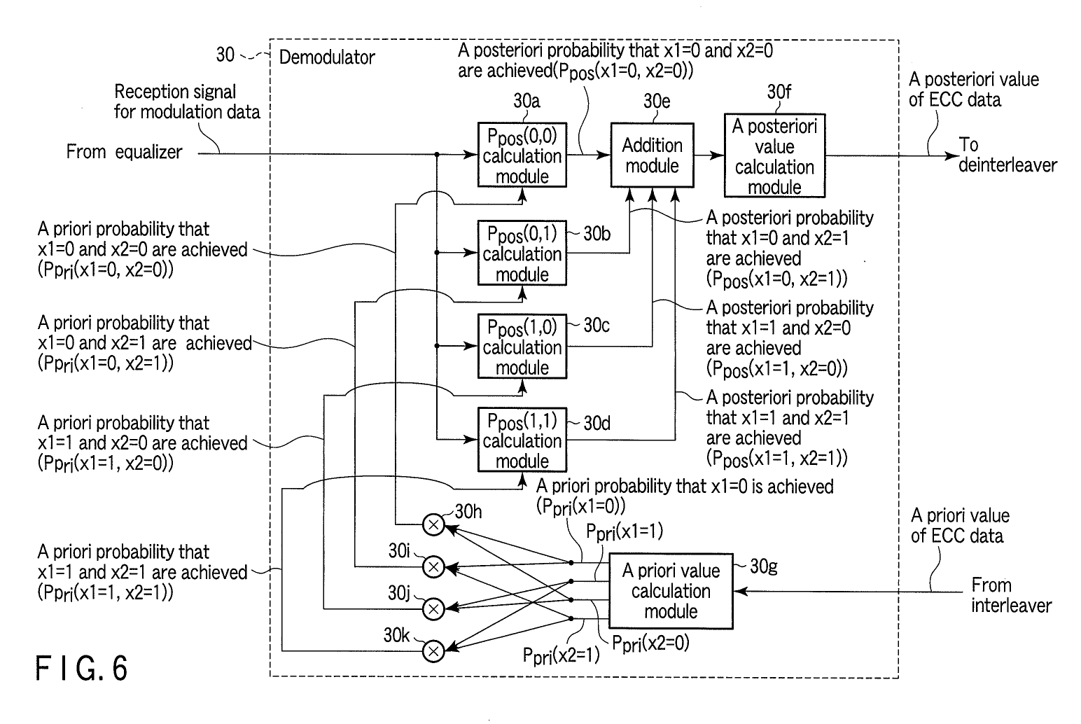

A calculation method for the a posteriori value of the ECC data in the demodulator 30 will now be explained. FIG. 6 is a structural view of the demodulator 30. Like the explanation of modulation, a structure of a 2:4 modulation code is a structure depicted in FIG. 2, and a structure of the reception signal for the modulation data is a structure depicted in FIG. 4.

An a priori probability of each ECC data is first calculated from an a priori value of the ECC data of two bits input to the demodulator 30. The a priori probability is obtained by an a priori probability calculation module 30g. An a priori probability calculation module 30g outputs an a priori probability that x1 is zero, an a priori probability that x1 is one, an a priori probability that x2 is zero, and an a priori probability that x2 is one.

Assuming that an a priori value Vₚᵣᵢ(x1) of ECC data x1 is Expression 15, an a priori probability Pₚᵣᵢ(x1=0) that x1 is zero becomes Expression 16, and an a priori probability Pₚᵣᵢ(x1=1) that ECC data is one becomes Expression 17. An a priori probability of another piece of ECC data x2 is obtained in the same manner.

$$\begin{matrix}{V}_{pos} ( x 2 ) = log \frac{{P}_{pos} ( x 2 = 1 )}{{P}_{pos} ( x 2 = 0 )} & Expression 15 \\ {P}_{pri} ( x 1 = 0 ) = \frac{1}{1 + exp ( {V}_{pri} ( x 1 ) )} & Expression 16 \\ {P}_{pri} ( x 1 = 1 ) = \frac{exp ( {V}_{pri} ( x 1 ) )}{1 + exp ( {V}_{pri} ( x 1 ) )} & Expression 17\end{matrix}$$

After the a priori probability is obtained from the a priori value of each ECC data, each a priori probability is input to each of a P_{POS}(0,0) calculation module 30a to a P_{POS}(1,1) calculation module 30d. For example, when inputting to the P_{POS}(0,0) calculation module 30a, Pₚᵣᵢ(x1=0) and Pₚᵣᵢ(x2=0) are input to an integrator 30h to be multiplied, and then a value of Pₚᵣᵢ(x1=0)×Pₚᵣᵢ(x2=0) is input to the P_{POS}(0,0) calculation module 30a.

Further, when inputting to the P_{POS}(0,1) calculation module 30b, Pₚᵣᵢ(x1=0) and Pₚᵣᵢ(x2=1) are input to an integrator 30i to be multiplied, and then a value of Pₚᵣᵢ(x1=0)×Pₚᵣᵢ(x2=1) is input to the P_{POS}(0,1) calculation module 30b. Furthermore, when inputting to the P_{POS}(1,0) calculation module 30c, Pₚᵣᵢ(x1=1) and Pₚᵣᵢ(x2=0) are input to an integrator 30j to be multiplied, and then a value of Pₚᵣᵢ(x1=1)×Pₚᵣᵢ(x2=0) is input to the P_{POS}(1,0) calculation module 30c. Additionally, when inputting to the P_{POS}(1,1) calculation module 30d, Pₚᵣᵢ(x1=1) and Pₚᵣᵢ(x2=1) are input to an integrator 30k to be multiplied, and then a value of Pₚᵣᵢ(x1=1)×Pₚᵣᵢ(x2=1) is input to the P_{POS}(1,1) calculation module 30d.

After the respective a priori probabilities are input to the probability calculation module, a posteriori probabilities P_{POS}(x1=0, x2=0) to P_{POS}(x1=1, x2=1) are calculated from the a priori probabilities and the reproduction signal. The respective a posteriori probabilities are as represented by Expressions 18 to 21. Here, P′_{POS}(x1=0, x2=0) to P′_{POS}(x1=1, x2=1) in Expressions 18 to 21 are the same as Expressions 5 to 8, respectively.

Pₚₒₛ(x1=0,x2=0)=Pₚᵣᵢ(x1=0)*Pₚᵣᵢ(x2=0)*P′ₚₒₛ(x1=0,x2=0) Expression 18

Pₚₒₛ(x1=1,x2=0)=Pₚᵣᵢ(x1=1)*Pₚᵣᵢ(x2=0)*P′ₚₒₛ(x1=1,x2=0) Expression 19

Pₚₒₛ(x1=0,x2=1)=Pₚᵣᵢ(x1=0)*Pₚᵣᵢ(x2=1)*P′ₚₒₛ(x1=0,x2=1) Expression 20

Pₚₒₛ(x1=1,x2=1)=Pₚᵣᵢ(x1=1)*Pₚᵣᵢ(x2=1)*P′ₚₒₛ(x1=1,x2=1) Expression 21

After the respective a posteriori probabilities P_{POS}(x1=0, x2=0) to P_{POS(x1=}1, x2=1) are obtained, a posteriori values of the ECC data are calculated. A posteriori values V_{POS}(x1) and V_{POS}(x2) of respective pieces of data are as represented by Expressions 22 and 23.

$$\begin{matrix}{V}_{pos} ( x 1 ) = log \frac{{P}_{pos} ( x 1 = 1 , x 2 = 0 ) + {P}_{pos} ( x 1 = 1 , x 2 = 1 )}{\begin{matrix}{P}_{pos} ( x 1 = 0 , x 2 = 0 ) + \\ {P}_{pos} ( x 1 = 0 , x 2 = 1 )\end{matrix}} & Expression 22 \\ {V}_{pos} ( x 2 ) = log \frac{{P}_{pos} ( x 1 = 0 , x 2 = 1 ) + {P}_{pos} ( x 1 = 1 , x 2 = 1 )}{\begin{matrix}{P}_{pos} ( x 1 = 0 , x 2 = 0 ) + \\ {P}_{pos} ( x 1 = 1 , x 2 = 0 )\end{matrix}} & Expression 23\end{matrix}$$

When performing demodulation for the first time, which one of a probability that the ECC data is zero and a probability that the ECC data is one is high is unknown. Therefore, an initial value of the a priori value of the ECC data is determined as zero. When the a priori value is set to zero, both the a priori probability that the ECC data is zero and the a priori probability that the same is one are 0.5. If a data distribution of the ECC data is biased and how this data is biased is known, the a priori value may be set to an appropriate value.

Further, as explained above, the external value of the ECC data fed back from the turbo/LDPC decoder is directly assigned to the a priori value of the ECC data when performing demodulation for the second or subsequent time.

As explained above, the a priori probability calculation module 30g and the integrators 30h to 30k are provided in the demodulator 30. Furthermore, since each a posteriori value of the ECC data is calculated based on probabilities of all patterns of the modulation code, it can be understood that a modulation calculation amount is dependent on the number of patterns of the modulation data. Therefore, since the number of patterns (2̂m) of the modulation code exponentially rises when an information data bit number m is increased, there is a problem of an extreme increase in demodulation calculation amount.

Considering a signal processing system that performs iterative decoding between the demodulator and the turbo/LDPC decoder, the above-explained problem adversely affects a decoding calculation amount of the signal processing system.

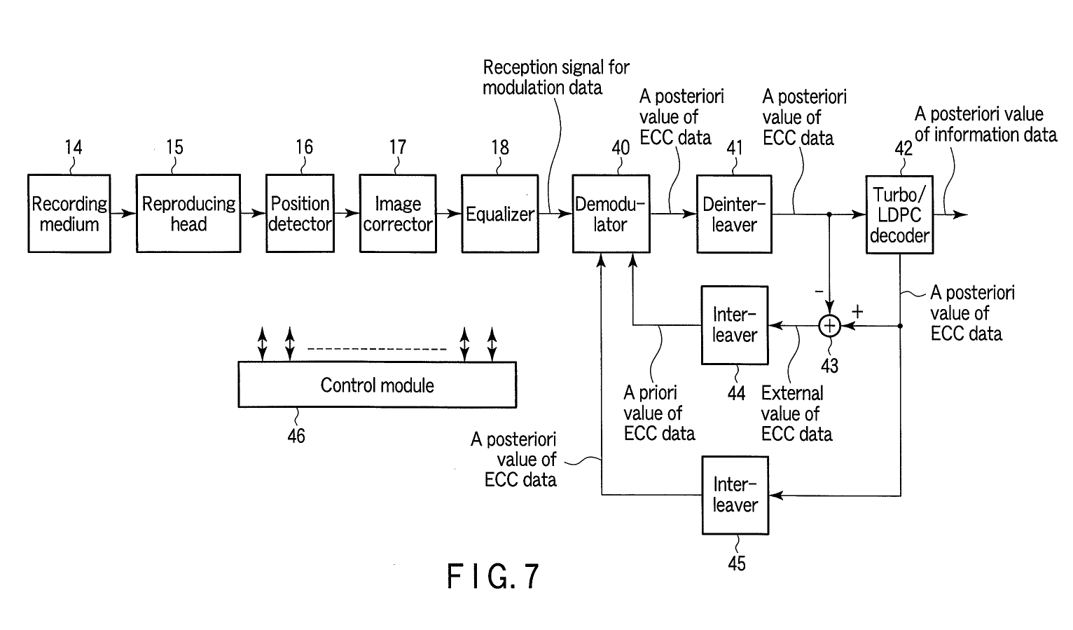

Thus, the present invention provides an ingenious signal processing system explained below. FIG. 7 is a signal processing system block diagram according to the present invention.

A basic flow of the entire signal processing system is substantially the same as that in the conventional technology. A recording medium 14, a reproducing head 15, a position detector 16, an image corrector 17, and an equalizer 18 are the same as those in the structure depicted in FIG. 5.

An a posteriori value of ECC data demodulated in a demodulator 40 is input to a turbo/LDPC decoder 42 to be decoded through a deinterleaver 41. The a posteriori value of the ECC data obtained in this turbo/LDPC decoder 42 is input to a subtracter 43 and also input to an interleaver 45. The subtracter 43 subtracts the a posteriori value of the ECC data before updating from the posterior value of the ECC data after updating and inputs an output (an output as an external value of the ECC data) to an interleaver 44. Moreover, an output from the interleaver 45 is also input to the demodulator 40 as an a posteriori value of the ECC data.

In the apparatus according to the present invention, as data that is fed back to the demodulator 40 in a calculation method for an a posteriori value of the ECC data when performing demodulation for the second time, there are not only an a priori value of the ECC data but also an a posteriori value of the ECC data. Demodulation carried out for the first time is the same as that in the method explained in conjunction with FIG. 5. Additionally, when effecting demodulation for the second or subsequent time, modulation data is narrowed down based on the fed-back a priori value of the ECC data to calculate an a posteriori value of the ECC data.

It is to be noted that the entire block is controlled by a controller 46, and an operation clock, an operation timing, and others are integrally controlled.

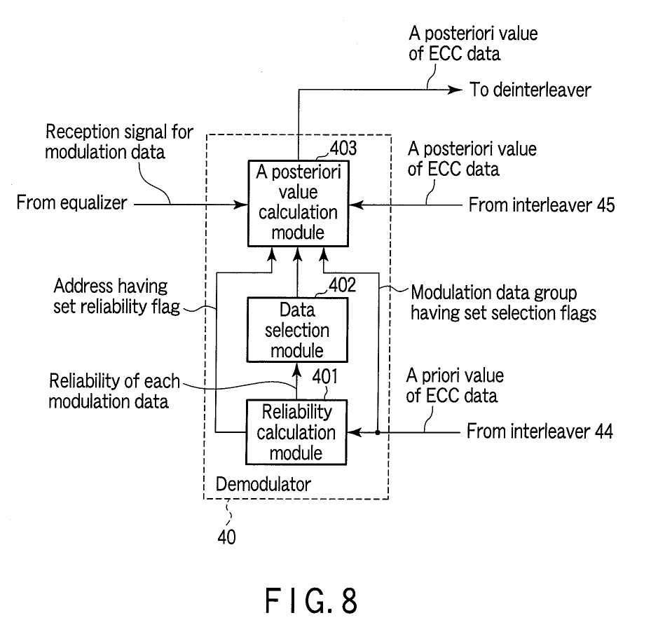

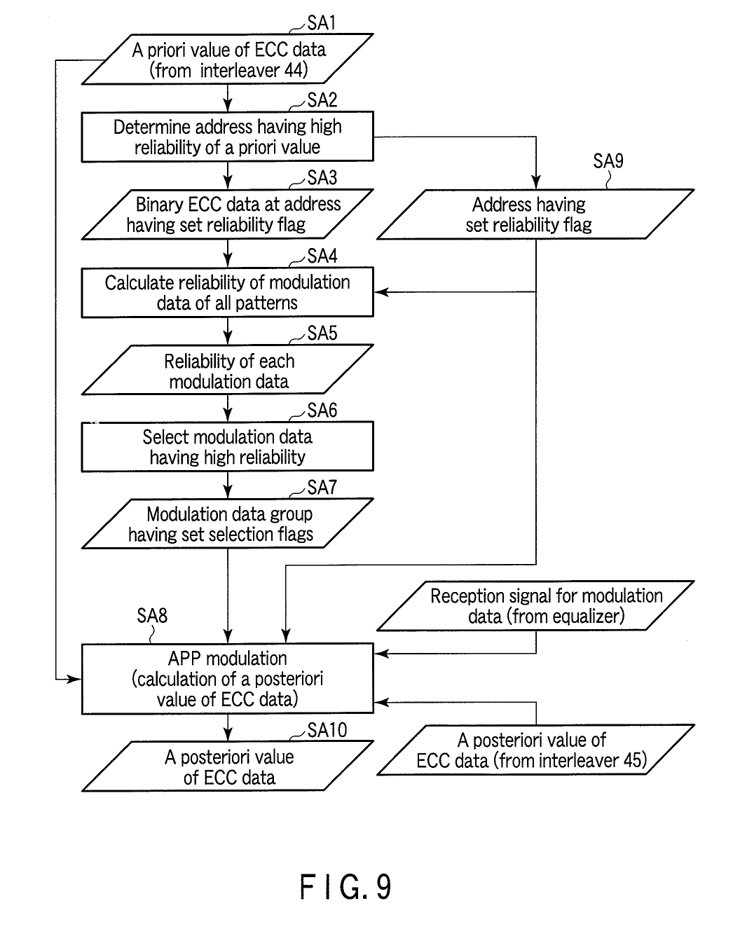

An outline of the modulation method carried out for the second or subsequent time in the present invention will now be explained. FIG. 8 is a structural view of a demodulator, and FIG. 9 is a flowchart of the demodulation method carried out for the second or subsequent time. An outline of a demodulation procedure will be explained with reference to FIGS. 8 and 9.

A reliability calculation module 401 first determines an address having high reliability of an a priori value and binary ECC data at this address based on an a priori value of the ECC data fed back from the interleaver 44 (steps SA1, SA2, SA3, and SA9 in FIG. 9), and calculates reliability of modulation data of all patterns (2̂m=2 raised to the mth power) (steps SA4 and SA5 in FIG. 9). Then, a data selection module 402 selects modulation data having high reliability based on calculated reliability of each modulation data (steps SA6 and SA7 in FIG. 9). At last, an a posteriori value calculation module 403 calculates an a posteriori value of the ECC data from the a priori value of the ECC data or the a posteriori value of the ECC data fed back from the interleavers 44 and 45, an address having high reliability of an a priori value, and a reception signal for the modulation data (steps SA 8 and SA10 in FIG. 9).

Subsequently, various operations of respective parts in the reliability calculation module 401, the data selection module 402, and the a posteriori value calculation module 403 as primary modules in the demodulator 40 will now be explained.

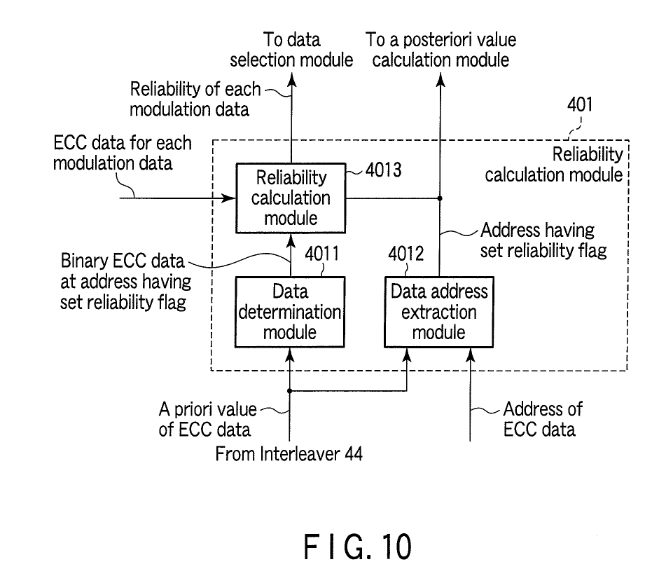

A procedure of calculating reliability of each modulation data in the reliability calculation module 401 will be first explained. FIG. 10 is a structural view of the reliability calculation module 401. As shown in FIG. 10, the reliability calculation module 401 has a data determination module 4011, a data address extraction module 4012, and a reliability calculation module 4013. First, the data determination module 4011 and the data address extraction module 4012 determine an address having high reliability of an a priori value and binary ECC data at this address from an a priori value of the ECC data fed back from the interleaver 44 and an address for the ECC data. Further, the reliability calculation module 4013 calculates reliability of each modulation data from the address having high reliability of an a priori value, the binary ECC data at this address, and the ECC data for modulation data of all patterns (2̂m), and the processing is terminated.

The address for the ECC data means, e.g., an address given to the ECC data in each block in units of demodulation processing. For example, in case of a 2-4 modulation scheme, this address is an address associated with the foregoing data x1 or x2.

The binary ECC data (associated with an address having a set reliability flag) determined by the data determination module 4011 is input to the reliability calculation module 4013. Furthermore, the address having the set reliability flag obtained by the data address extraction module 4012 is transmitted to the reliability calculation module 4013 and the a posteriori calculation module 403.

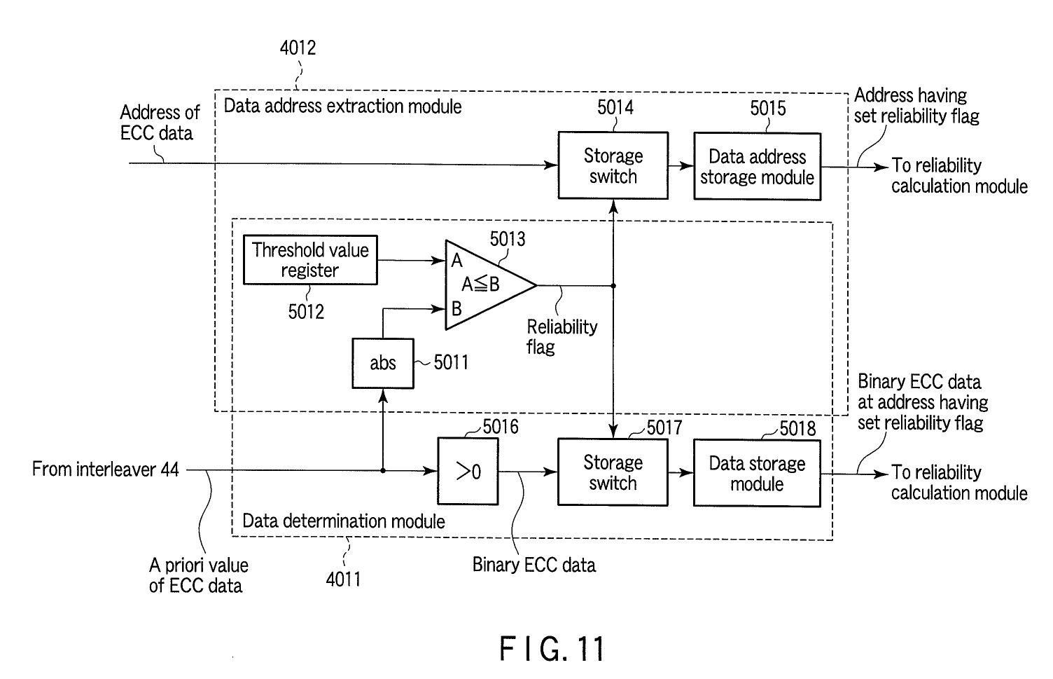

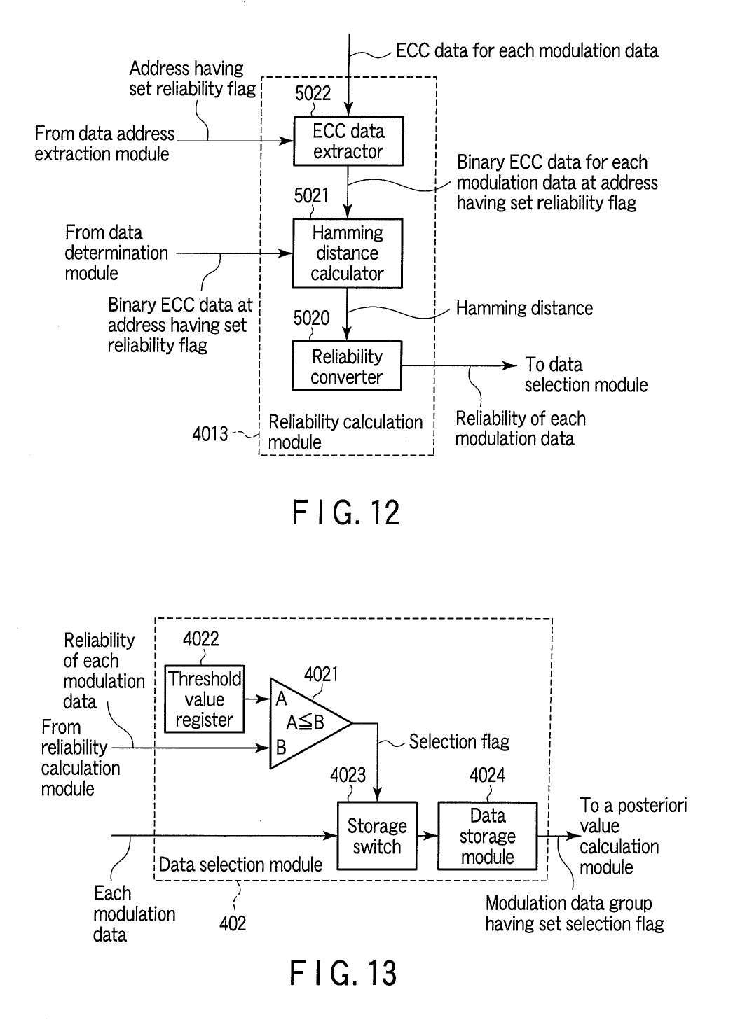

Then, the data determination module 4011, the data address extraction module 4012, and the reliability calculation module 4013 will now be explained with reference to FIGS. 11 and 12.

In FIG. 11, the address having high reliability of an a priori value output from the data determination module 4011 and the data address extraction module 4012 can be obtained from an absolute value of the a priori value of the ECC data. Moreover, the binary ECC data at this address can be obtained from a positive and a negative of the a priori value of the ECC data.

First, when obtaining the address having high reliability of an a priori value, an absolute value converter 5011 obtains an absolute value of the a priori value of the ECC data, and a comparator 5013 determines whether this absolute value is larger than a threshold value. The threshold value is stored in a threshold value register 5012. When the absolute value of the a priori value of the ECC data is larger than the threshold value, the a priori value of the ECC data is considered to have high reliability, and a reliability flag is set. When the reliability flag is set, a storage switch 5014 is turned on, and the address of the ECC data is stored in a data address storage module 5015.

On the other hand, when obtaining the binary ECC data for this address, the a priori value of the ECC data is first input to a hard determination module 5016, and an output from the hard determination module 5016 is determined as binary ECC data. This method is the same as a method of determining binary information data from an a posteriori value of information data. Additionally, the ECC data at the address having high reliability alone is stored in a data storage module 5018 through a storage switch 5017 based on the reliability flag output from the comparator 5013

Determining reliability based on the threshold value in this manner enables storing both the address having high reliability and the ECC data at this address. These pieces of data are supplied to the reliability calculation module 4013.

After obtaining the address having high reliability and the binary ECC data at this address, the reliability calculation module 4013 depicted in FIG. 12 calculates reliability of each modulation data. The reliability calculation module 4013 has a reliability converter 5020, a Hamming distance calculator 5021, and an ECC data extractor 5022.

The reliability of each modulation data is calculated based on a Hamming distance between ECC data obtained from an a priori value and the ECC data for each modulation data at an address having a set reliability flag. In this embodiment, the highest reliability is provided when the Hamming distance is zero, and the reliability is lowered as the distance is increased.

The ECC data extraction module 5022 receives the ECC data (which is currently a processing target) for each modulation data and the address having the set reliability flag (which is output from the above-explained data address extraction module 4012).

Then, the ECC data for each modulation data at this address is obtained. Further, the Hamming distance calculator 5021 calculates a Hamming distance between the ECC data obtained from the a priori value (data from a feedback system) and the ECC data for each modulation data at this address. At last, the reliability converter 5020 converts the Hamming distance into reliability of the modulation data, thereby terminating calculation of reliability for each modulation data. This reliability of each modulation data is input to the data selection module 402.

After the reliability calculation module 401 outputs reliability of each modulation data, the data selection module 402 depicted in FIG. 13 selects modulation data based on each reliability. First, the reliability of each modulation data output from the reliability calculation module 401 is input to a comparator 4021, and whether this reliability is larger than a predetermined threshold value is determined. The threshold value is stored in a threshold value register 4022. When the reliability of the modulation data is larger than the threshold value, the target modulation data is considered to have high reliability, and a selection flag is set. When the selection flag is set, a storage switch 4023 is turned on, and a selected modulation data group is stored in a storage module 4024. The selected modulation data group is supplied to an a posteriori calculation module 403.

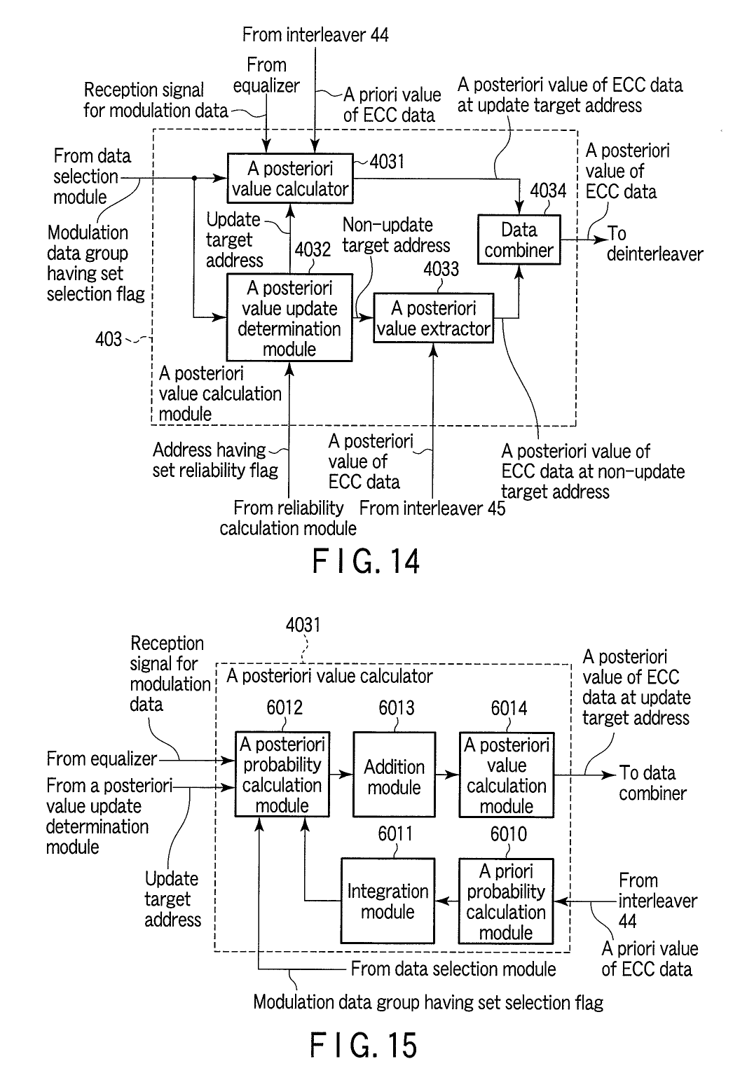

After selecting the modulation data having high reliability, the a posteriori value calculation module 403 depicted in FIG. 14 calculates an a posteriori value of the ECC data. The a posteriori calculation module 403 includes an a posteriori value calculator 4031, an a posteriori value update determination module 4032, an a posteriori extractor 4033, and a data combiner 4034. The a posteriori value calculator 4031 receives a modulation data group having set selection flags from the data selection module 402, a reception signal for the modulation data from the equalizer, and an a priori value of the ECC data from the interleaver 44. Furthermore, it also receives an update target address from the a posteriori value update determination module 4032.

The a posteriori value update determination module 4032 receives an address having a set reliability flag from the reliability calculation module 401 and a modulation data group having set selection flags from the data selection module 402. The a posteriori value update determination module 4032 supplies a non-update target address to the a posteriori extractor 4033. The a posteriori extractor 4033 selects an a posteriori value of the ECC data from the interleaver 45 based on the non-update target address, outputs the a posteriori value of the ECC data at the non-update target address, and supplies this value to the data combiner 4034. This data combiner 403 also receives an a posteriori value of the ECC data at an update target address calculated by the a posteriori calculator 4031.

As explained above, the a posteriori calculation module 403 sorts each address at which an a posteriori value is updated (an update target address) and each address at which an a posteriori value is not updated (a non-update target address) based on the selected modulation data group and the addresses having set reliability flags. As to an a posteriori value of the ECC data at an update target address, a value is obtained in the same format as Expressions 18 to 23 and then updated by the a posteriori value calculator 4031. In regard to an a posteriori value of the ECC data at a non-update target address, the a posteriori value extractor 4033 extracts a value associated with a corresponding address from a posteriori values of the ECC data fed back from the interleaver 45.

Furthermore, the data combiner 4034 combines the a posteriori value of the ECC data output from the a posteriori value calculator 4031 with the a posteriori value of the ECC data output from the a posteriori value extractor 4033 to be determined as an a posteriori value of the ECC data after demodulation, and supplies the obtained value to the deinterleaver 41. Then, the demodulation calculation is terminated.

In regard to how to sort addresses, several patterns can be considered. First, there is a method of determining all addresses having set reliability flags as non-update target addresses. Besides, it is possible to adopt a method of determining addresses having the same data as non-update target addresses when such addresses are found at the time of checking the ECC data for selected modulation data.

As explained above, the calculation method for an a posteriori value of the ECC data in the a posteriori value calculator 4031 depicted in FIG. 15 is the same as that in the conventional technology except that selected modulation data is utilized. First, an a priori probability of the ECC data is passed to an a priori probability calculation module 6010 and an integration module 6011 in the mentioned order to calculate an a priori probability of each modulation data. Moreover, an a posteriori probability calculation module 6012, an addition module 6013, and an a posteriori calculation module 6014 calculate an a posteriori value of the ECC data at a fine calculation address based on a reception signal for modulation data, a selected modulation data group, and an a priori probability of each modulation data.

FIG. 9 is an operation flowchart collectively showing the above-explained operations.

### Effects of Present Embodiment

Adopting the foregoing embodiment enables narrowing down modulation data based on an a priori value of ECC data at the time of demodulation carried out for the second time, thus decreasing a decoding calculation amount and increasing a decoding speed. Additionally, considering data corresponding to one page in hologram recording, demodulation calculation can be substantially simplified with respect to a part that has a high quality of a reception signal and also has high reliability of an a posteriori value or an a priori value, and demodulation calculation can be concentrated on a part that has a low quality of a reception signal and has low reliability of an a posteriori value or an a priori value.

Further, Patent Document 2 describes a method of calculating a probability of each modulation data from a reception signal for each modulation data and utilizing the modulation data having a high probability alone for calculation of an a posteriori value, but this embodiment utilizes an a priori value of ECC data to make a selection without using a reception signal, thereby decreasing a calculation amount for the selection. Furthermore, since calculation for an a posteriori value itself is not carried out in regard to an address having high reliability, a calculation amount at this address can be substantially zero. These effects become more prominent when the number m of pieces of input data is increased.

### SPECIFIC NUMERICAL EXAMPLE

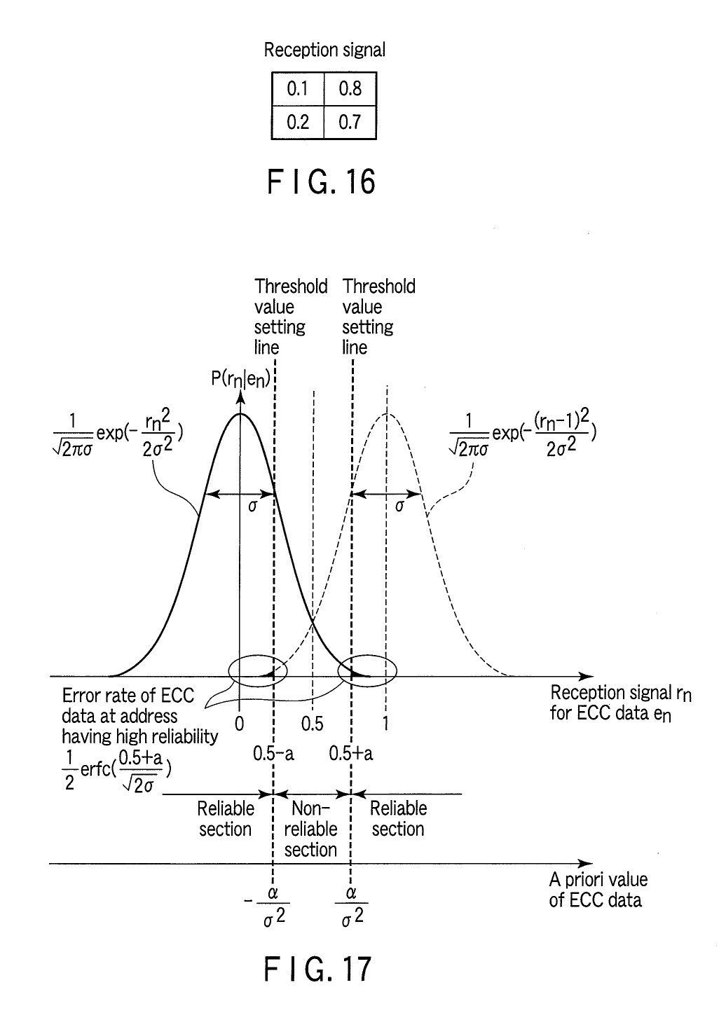

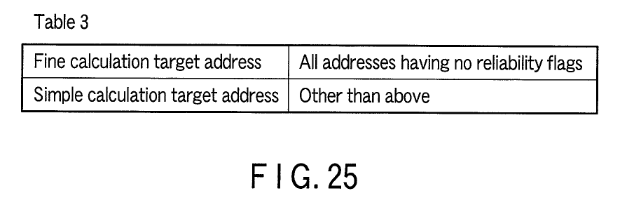

Specific numerical values will now be taken as an example to explain operations in the present invention. Table 1 in FIG. 23 shows a setting example of a threshold value for a reliability determination and a threshold value for a modulation data selection, Table 2 in FIG. 24 shows a conversion example from a Hamming distance that appears in the reliability calculation module into reliability, and Table 3 in FIG. 25 shows a determination reference example of a posteriori value calculation addresses in the a posteriori calculation module. Further, FIG. 2 shows a structure of a modulation code, and FIG. 16 shows an example of a reception signal for modulation data. Furthermore, both a priori values of respective pieces of ECC data x1 and x2 at the time of modulation carried out for the first time are zero.

Assuming that a threshold value of the reliability determination flag is a value in Table 1 in FIG. 23, an address at which an a priori probability of one piece of ECC data is equal to or above 90% and an a priori probability of the other piece of ECC data is equal to or below 10% is regarded as an address that the reliability flag is set. When a threshold value for a modulation data selection is as shown in Table 1 in FIG. 23 and a conversion example from a Hamming distance to reliability is as shown in Table 2 in FIG. 24, the data selection module selects modulation data whose ECC data completely matches with binary ECC data at the address having the set reliability flag alone output from the data determination module.

When a determination on an a posteriori value calculation address is as shown in Table 3 in FIG. 25, an a posteriori value of ECC data is finely calculated and updated at an address having no reliability flag, and the a posteriori value is not updated at an address having a set reliability flag.

A reception signal for modulation data depicted in FIG. 16 is first modulated based on Expressions 15 to 23 to calculate an a posteriori value of each ECC data. As a result, a posteriori values of the respective pieces of ECC data x1 and x2 are [−1.2 −0.1072]. Each calculated a posteriori value of the ECC data means that a probability for realization of zero is high. In terms of specific numerical values, an a posteriori probability that x1=0 is achieved is approximately 76%, and an a posteriori probability that x2=0 is attained is approximately 52%. The possibility that x1=0 is achieved is considerably high, and which one of 0 and 1 that x2 corresponds to is hardly determined.

After calculating a posteriori values of the ECC data in the demodulator and reordering the a posteriori values of the ECC data in the deinterleaver, the reordered data is input as communication path values of the ECC data to the turbo/LDPC decoder to correct an error. Although a description on particulars will be omitted, it is assumed that an error is detected as a result of error correction and the a posteriori values of the ECC data (x1, x2) are respectively calculated as values [−4 −0.2].

Then, the input communication path values of the ECC data are subtracted from the a posteriori values of the ECC data calculated by the decoder in order to obtain a priori values of the ECC data that are input to the demodulator, thereby obtaining external values of the ECC data. The values are [−4 −0.2]−[−1.2 −0.1072]=[−2.8 −0.0928]. Further, the values are reordered by the interleaver, and they are input as a priori values of the ECC data to the demodulator.

Subsequently, the second modulation is performed. First, the reliability calculation module obtains an address that the reliability flag is set and reliability of each modulation from the a priori values ([−2.8 −0.0928]) of the ECC data input to the demodulator.

The data address extraction module obtains an address that the reliability flag is set. Since absolute values of the a priori values of the ECC data are [2.8 0.0928], an address of x1 alone becomes an address that the reliability flag is set. Furthermore, the address of x1 alone becomes a storage target, and the data determination module obtains x1=0 from the a priori value (−2.8) of the ECC data x1.

That is, the address of x1 becomes the address that the reliability flag is set, and the ECC data at this address becomes zero.

Upon receiving results output from the data address extraction module and the data determination module, reliability of each modulation data is calculated. First, ECC data for each modulation data at the address having the set reliability flag is obtained. Respective pieces of ECC data having codes C1 to C4 at the address of x1 are [0, 1, 0, 1], respectively. Then, Hamming distances between respective pieces of extracted ECC data and the ECC data output from the data determination module are calculated. The Hamming distances are [0, 1, 0, 1], respectively. At last, reliability for each modulation data is calculated from the Hamming distances. The reliabilities of the respective pieces of modulation data become [1 0 1 0] from Table 2 in FIG. 24.

That is, the codes C1 and C3 with which the ECC data x1=0 is attained are regarded as respective pieces of modulation data having high reliability. Then, the operation in the reliability calculation module is terminated.

After the reliability calculation module obtains the address having the set reliability flag and the reliability of each modulation data, the data selection module narrows down the modulation data. Based on the reliability of each modulation data ([1, 0, 1, 0]) and the threshold value for the modulation data selection shown in Table 1 in FIG. 23, the selection flags are set with respect to the code C1 and the code C3, and the two codes remain. That is, each of code C1 and the code C3 remains as modulation data having high reliability and is used for the last calculation of an a posteriori value of each ECC data.

After the modulation data is selected, the a posteriori value calculation module calculates the a posteriori value of each ECC data. First, a fine calculation address and a simple calculation address are determined. The a posteriori value update determination module determines from a determination standard shown in Table 3 that the a posteriori value of x1 is not updated but the a posteriori value of x2 is updated. As the a posteriori value of x1, the a posteriori value input to the demodulator is directly input to the data combiner. The a posteriori value of x2 is calculated in the same format as Expressions 15 to 23 by utilizing the selected codes C1 and C3 alone by an a posteriori value fine calculator. Then, the a posteriori value of x2 can be obtained as represented by Expression 24. Here, P′_{POS}(x1=0, x2=0) and P′_{POS}(x1=0, x2=1) in Expression 24 are the same as those in Expressions 5 and 7.

$$Vpos ( x 2 ) = \frac{\begin{matrix}{P}_{pri} ( x 1 = 0 ) * {P}_{pri} ( x 2 = 1 ) * \\ {P}_{pos}^{′} ( x 1 = 0 , x 2 = 1 )\end{matrix}}{\begin{matrix}{P}_{pri} ( x 1 = 0 ) * {P}_{pri} ( x 2 = 0 ) * \\ {P}_{pos}^{′} ( x 1 = 0 , x 2 = 0 )\end{matrix}} \\ = - 0.2928 \qquad Expression 24$$

A method of determining a threshold value required to determine reliability of the a priori value of the ECC data will now be explained. The threshold value required to determine reliability of the a priori value of the ECC data is determined based on noise included in a reception signal for the ECC data and a set value of an error rate of the ECC data at an address determined to have high reliability.

The error rate of the ECC data at the address determined to have high reliability will now be explained. The error rate is equal to an error rate of ECC data when the threshold value required to determine reliability of the ECC data is set at a give value, and it is calculated from a probability distribution of a reception signal for the ECC data.

FIG. 17 is a view showing a relationship between a probability distribution of a reception signal for the ECC data and the threshold value. In FIG. 17, noise included in the reception signal for the ECC data is white gaussian noise having a standard deviation σ. Further, when the reception signal for the ECC data is lower than (0.5−a), the ECC data is determined as “0”. Contrary, when this reception signal is higher than (0.5+a), the ECC data is determined as “1”. That is, when the reception signal is lower than (0.5−a) and higher than (0.5+a), the reception signal is considered to have high reliability.

Assuming that Expression 25 represents a probability distribution of the reception signal when the ECC data is zero and Expression 26 represents a probability distribution of the reception signal when the ECC data is one, an a priori value of the ECC data when the reception signal for the ECC data is (0.5−a) and an a priori value of the ECC data when the reception signal is (0.5+a) are represented by Expression 27.

$$\begin{matrix} Expression 25 \\ P ( {r}_{n} \vert {e}_{n} = 0 ) = \frac{1}{\sqrt{2 π} σ} exp ( - \frac{{r}_{n}^{2}}{2 {σ}^{2}} ) \\ Expression 26 \\ P ( {r}_{n} \vert {e}_{n} = 1 ) = \frac{1}{\sqrt{2 π} σ} exp ( - \frac{{( {r}_{n} - 1 )}^{2}}{2 {σ}^{2}} ) \\ Expression 27 \\ When the reception signal for the ECC data is ( 0.5 + a ) , \\ log \frac{P ( {r}_{n} = ( 0.5 + a ) \vert {e}_{n} = 1 )}{P ( {r}_{n} = ( 0.5 + a ) \vert {e}_{n} = 0 )} = log \frac{\frac{1}{\sqrt{2 π} σ} exp ( - \frac{{( ( 0.5 + a ) - 1 )}^{2}}{2 {σ}^{2}} )}{\frac{1}{\sqrt{2 π} σ} exp ( - \frac{{( 0.5 + a )}^{2}}{2 {σ}^{2}} )} = \\ \frac{- {( ( 0.5 + a ) - 1 )}^{2} + {( 0.5 + a )}^{2}}{2 {σ}^{2}} = \frac{a}{{σ}^{2}} \\ When the reception signal for the ECC data is ( 0.5 - a ) , \\ log \frac{P ( {r}_{n} = ( 0.5 - a ) \vert {e}_{n} = 1 )}{P ( {r}_{n} = ( 0.5 - a ) \vert {e}_{n} = 0 )} = log \frac{\frac{1}{\sqrt{2 π} σ} exp ( - \frac{{( ( 0.5 - a ) - 1 )}^{2}}{2 {σ}^{2}} )}{\frac{1}{\sqrt{2 π} σ} exp ( - \frac{{( 0.5 - a )}^{2}}{2 {σ}^{2}} )} = \\ \frac{- {( ( 0.5 - a ) - 1 )}^{2} + {( 0.5 - a )}^{2}}{2 {σ}^{2}} = - \frac{a}{{σ}^{2}}\end{matrix}$$

Therefore, in the example depicted in FIG. 17, the threshold value required to determine reliability of the ECC data is (a/σ²).

In regard to an error rate when the threshold value required to determine reliability of the ECC data is (a/σ²), it is good enough to obtain a probability that an a priori value of the ECC data becomes equal to or above (a/σ²), i.e., the reception signal for the ECC data becomes equal to or above (0.5+a) when the ECC data is zero. This probability is as represented by Expression 28 when an error function erfc is used.

$${\int }_{0.5 + a}^{∞} \frac{1}{\sqrt{2 π} σ} exp ( - \frac{{r}_{n}^{2}}{2 {σ}^{2}} ) d {r}_{n} = \frac{1}{2} erfc ( \frac{0.5 + a}{\sqrt{2} σ} ) \qquad Expression 28$$

Therefore, an error rate B of the ECC data at an address having high reliability when the threshold value required to determine reliability is as represented by Expression 29. Contrary, the threshold value A that attains the error rate B of the ECC data at the address having high reliability is as represented by Expression 30 when an inverse function of the error function erfc is erfc⁻¹.

$$\begin{matrix}B = \frac{1}{2} erfc ( \frac{0.5 + A {σ}^{2}}{\sqrt{2} σ} ) & Expression 29 \\ A = \frac{\sqrt{2}}{σ} {erfc}^{- 1} ( 2 B ) - \frac{1}{2 {σ}^{2}} & Expression 30\end{matrix}$$

That is, when setting the threshold value required to determine reliability of the a priori value of the ECC data, it is good enough to set the error rate of the ECC data at the address having high reliability and set the threshold value based on Expression 30.

The noise included in the reception signal for the ECC data is obtained by previously preparing a correspondence table of noise included in a reception signal for modulation data and the noise included in the reception signal for the ECC data, measuring the noise included in the reception signal for the modulation data at the time of reproduction, and then performing calculation based on the prepared correspondence table and the measured noise.

A method of creating the correspondence table of the noise included in the reception signal for the modulation data and the noise included in the reception signal for the ECC data will now be explained.

At the time of decoding, the ECC data can be obtained by demodulating the reception signal for the modulation data. Therefore, the modulation data obtained by modulating the known ECC data and noise included in the reception signal for the modulation data are prepared, the reception signal including the set noise is demodulated to obtain an a posteriori value of the ECC, and the noise included in the reception signal for the ECC is calculated from the a posteriori value. Further, a plurality of types of noise are set, and the same operation is repeated, thereby bringing the correspondence table to completion.

A method of calculating noise included in a reception signal for ECC data from an a posteriori value of the ECC data will now be explained.

The noise included in the reception signal for the ECC data can be obtained by converting a distribution of the a posteriori value of the ECC data into a distribution of the reception signal for the ECC data and calculating a probability density function of the reception signal distribution.

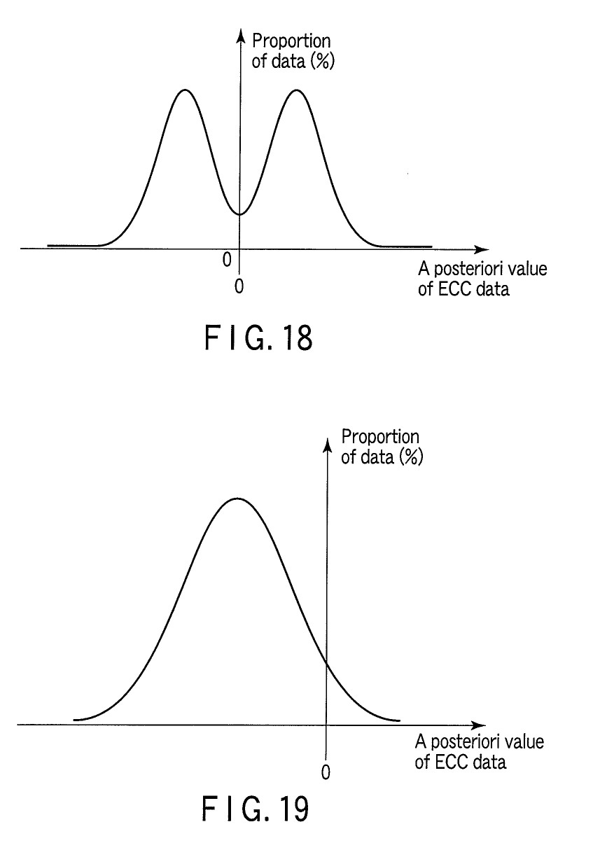

It is assumed that one type of noise included in the reception signal for the modulation data is set and a distribution of the a posteriori value of the ECC data obtained by demodulating the reception signal is as shown in FIG. 18.

Now, since the ECC data is known, the distribution depicted in FIG. 18 can be sorted depending on a situation where the ECC data is zero and a situation where the same is one. It is assumed that an example of a distribution of the a posteriori value of the ECC data when the ECC data is zero after sorting is as shown in FIG. 19.

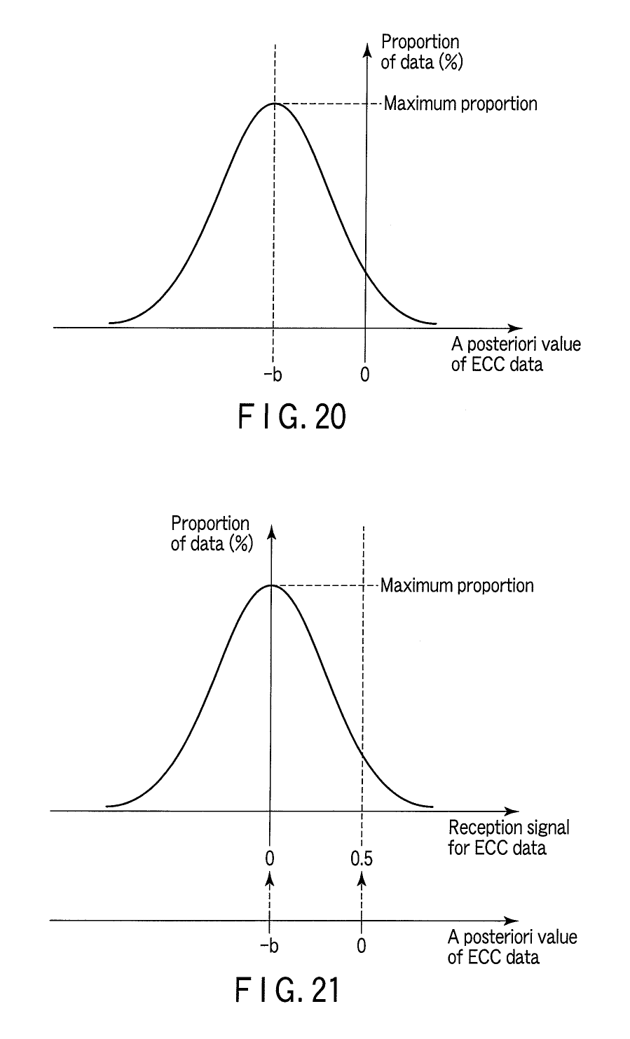

Subsequently, as shown in FIG. 20, an a posteriori value (−b) that maximizes a proportion of the data is obtained from the distribution of the a posteriori value of the ECC data when the ECC data is zero depicted in FIG. 19.

After the a posteriori value (−b) that maximizes the proportion of the data is obtained, the a posteriori value of the ECC data is converted into the reception signal for the ECC data.

When the a posteriori value of the ECC data is zero, each of a probability that the ECC data is zero and a probability that the same is one is 50% based on a definition of the a posteriori value. Therefore, whether the ECC data is zero or one cannot be determined. This state is the same as a state where the reception signal for the ECC data takes an intermediate value 0.5 between zero and one and the ECC data cannot be determined from the reception signal. Therefore, a state where the a posteriori value of the ECC data is zero is regarded as the state where the reception signal for the ECC data is 0.5. Further, a state where the a posteriori value (−b) maximizing the proportion of the data is provided is regarded as the state where the reception signal for the ECC data is zero. As a result of this conversion, a distribution of the reception signal for the ECC data is as shown in FIG. 21.

After the a posteriori value of the ECC data is converted into the reception signal for the ECC data, a probability distribution of the reception signal is obtained.

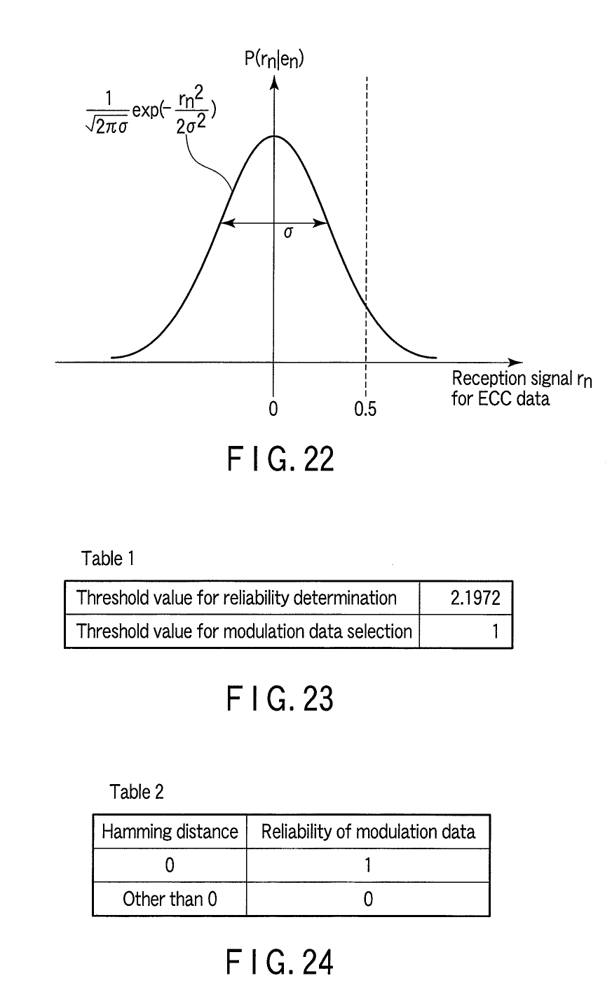

For example, in a case where the noise included in the reception signal for the ECC data is white gaussian noise, a probability density function of the reception signal in a situation where the ECC data is zero is as represented by Expression 31 when a dispersion value σ² of the noise is obtained (FIG. 22).

$$P ( {r}_{n} \vert {e}_{n} = 0 ) = \frac{1}{\sqrt{2 π} σ} exp ( - \frac{{r}_{n}^{2}}{2 {σ}^{2}} ) \qquad Expression 31$$

Therefore, when the ECC data is zero, the probability density function of the noise included in the reception signal for the ECC data is as represented by Expression 32.

$$P ( {n}_{i} ) = \frac{1}{\sqrt{2 π} σ} exp ( - \frac{{n}_{i}^{2}}{2 {σ}^{2}} ) \qquad Expression 32$$

In the above-explained operation, when the same calculation is carried out in regard to a case where the ECC data is one, a probability density function of the noise included in the ECC data can be obtained.

Further, when a plurality of types of noise included in the reception signal for the modulation data are set and the same operation is performed, a correspondence table of the noise included in the reception signal for the modulation data and the noise included in the reception signal for the ECC data is brought to completion.

Although the noise included in the reception signal for each of the modulation data and the ECC data is assumed as white gaussian noise in this embodiment, the present invention is not restricted to the white gaussian noise, and the present invention can be likewise carried out in any other noise distribution.

Furthermore, the present invention can be likewise carried out in a situation where properties of noise provided in the reception signal when the ECC data is zero are different from those of noise provided in the reception signal when the ECC data is one or a situation where a probability that the ECC data appears as zero is different from a probability that the same appears as one. However, in such a case, it is desirable to prepare two type of threshold values required to determine reliability of the ECC data, i.e., a positive value and a negative value.

Moreover, although the embodiment using the 2:4 modulation code has been explained, the present invention is not restricted to the 2:4 modulation code and it can be likewise carried out even if any other modulation code is used.

While certain embodiments of the inventions have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A signal processing device configured to decode encoded information, the device estimating information data from a reception signal for modulation data by iterative processing between a demodulator configured to demodulate data of n bits, where n is a first positive integer larger than a second positive integer m, obtained by modulating data of m bits based on a predetermined modulation rule into m bits and an error correction code (ECC) decoder and carrying out maximum a posteriori (MAP) probability decoding,
wherein the signal processing device comprises a module configured to calculate an a posteriori value after demodulation by calculating modulation data with a pattern estimated to be highly probable as modulation data to be decoded among all patterns of the modulation data to be decoded in calculation of the a posteriori value after demodulation based on an a priori value from the ECC decoder.

2. A signal processing device configured to decode encoded information, the device estimating information data from a reception signal for modulation data by performing iterative processing between a demodulator configured to demodulate data of n bits, where n is a first positive integer larger than a second positive integer m, obtained by modulating data of m bits based on a predetermined modulation rule into m bits and an ECC decoder and carrying out maximum a posteriori probability decoding,
wherein, when performing modulation for a second or subsequent time, the signal processing device comprises:
a reliability output module configured to output reliability of modulation data of all patterns based on an a priori value of ECC data from the ECC decoder to the demodulator;
a data selection module configured to select modulation data of high reliability based on the reliability obtained from the reliability output module; and
an a posteriori value calculator configured to output an a posteriori value of ECC data of m bits from the a priori value of the ECC data from the ECC decoder, an a posteriori value of the ECC data from the ECC decoder, the modulation data of high reliability selected by the data selection module, and a reception signal for the modulation data.

3. The device of claim 2, wherein the reliability calculator is configured to use a first address at which an absolute value of the a priori value of the ECC data is higher than a threshold value as an address of high reliability, to obtain binary ECC data at the first address from the a priori value of the ECC data, and then to calculate reliability of each modulation data from a Hamming distance between ECC data for modulation data at the address of high reliability and the binary ECC data obtained from the a priori value of the ECC data.

4. The device of claim 2, wherein the data selection module is configured to select modulation data whose reliability output from the reliability calculator is higher than a set threshold value alone from the modulation data of all patterns.

5. The device of claim 2, wherein the a posteriori value calculator is configured to sort addresses subject to calculation of the ECC a posteriori value into a first group comprising at least one address at which the ECC a posteriori value is updated and a second group comprising at least one address at which the ECC a posteriori value is not updated, configured to use the a priori value of the ECC data from the ECC decoder and a modulation data selected by the data selection module and to calculate the a posteriori value of the ECC data for the first group, and configured to use the a posteriori value of the ECC data from the ECC decoder for the second group.

6. The device of claim 3, wherein the reliability calculator is configured to determine the threshold value for determining reliability of the a priori value of the ECC data based on noise in a reception signal for the ECC data and a predetermined value of an error rate of the ECC data at the address of high reliability.

7. The device of claim 3, wherein the reliability calculator is configured to prepare a correspondence table between noise in a reception signal for modulation data and noise in the reception signal for the ECC data in advance, and to measure the noise in the reception signal for the modulation data at the time of reproduction, then to calculate the noise in the reception signal for the ECC data from the prepared correspondence table and the measured noise.

8. The device of claim 7, wherein the correspondence table is created from a plurality of types of predetermined noise in a reception signal for predetermined modulation data and noise of ECC data calculated from a posteriori value of the ECC data obtained by demodulating a reception signal for modulation data comprising each predetermined noise.

9. A signal processing method of decoding encoded information, the method estimating information data from a reception signal for modulation data by performing iterative processing between a demodulator that demodulates data of n bits, where n is a first positive integer larger than a second positive integer m, obtained by modulating data of m bits based on a predetermined modulation rule into m bits and an ECC decoder and carrying out maximum a posteriori probability decoding,
wherein, when performing modulation for a second or subsequent time, the method comprises:
obtaining reliability of modulation data of all patterns based on an a priori value of ECC data from the ECC decoder to the demodulator;
selecting modulation data of high reliability based on the obtained reliability; and
obtaining an a posteriori value of ECC data of m bits from an a priori value of the ECC data from the ECC decoder, an a posteriori value of the ECC data from the ECC decoder, the selected modulation data of high reliability, and a reception signal for the modulation data.

10. The method of claim 9, further comprising, when calculating the reliability:
using a first address at which an absolute value of the a priori value of the ECC data is higher than a threshold value as an address of high reliability;
obtaining binary ECC data at the first address from the a priori value of the ECC data; and
calculating reliability of each modulation data from a Hamming distance between ECC data for modulation data at the address of high reliability and the binary ECC data obtained from the a priori value of the ECC data.

11. The method of claim 9, wherein modulation data comprising reliability higher than a set threshold value alone is selected from the modulation data of all patterns when selecting the modulation data of high reliability.

12. The method of claim 9, wherein the calculating the a posteriori value further comprising:
sorting addresses subject to calculation of the ECC a posteriori value into a first group comprising at least one address at which the ECC a posteriori value is updated and a second group comprising at least one address at which the ECC a posteriori value is not updated;
using the a priori value of the ECC data from the ECC decoder and a modulation data selected by the data selection module in order to calculate the a posteriori value of the ECC data for the first group; and
using the a posteriori value of the ECC data from the ECC decoder for the second group.

13. The method of claim 10, wherein the threshold value for determining reliability of the a priori value of the ECC data is determined based on noise in a reception signal for the ECC data and a predetermined value of an error rate of the ECC data at the address of high reliability, while calculating the reliability.
